(19) United States
(12) Patent Application Publication
(10) Pub. No.: US 2024/0414883 A1
(43) Pub. Date: Dec. 12, 2024

(54) TUNABLE HEXAGONAL BORON CARBON NITRIDE HEAT SPREADER AND METHOD OF ADJUSTING ITS THERMAL AND ELECTRICAL CONDUCTIVITY

(71) Applicant: THE HONG KONG UNIVERSITY OF SCIENCE AND TECHNOLOGY, HONG KONG (CN)

(72) Inventors: ZHENGTANG LUO, HONG KONG (CN); PATRICK RYAN GALLIGAN, HONG KONG (CN)

(21) Appl. No.: 18/332,757

(22) Filed: Jun. 12, 2023

(51) Int. Cl. H05K 7/20; C01B 21/064; C09K 5/14; C23C 16/36

(52) U.S. Cl. CPC H05K 7/2039; C01B 21/0646; C09K 5/14; C23C 16/36; C01P 2002/76; C01P 2002/82; C01P 2002/85; C01P 2004/04; C01P 2006/32; C01P 2006/40

(57) ABSTRACT

A heat spreader composed of a hexagonal boron carbon nitride (hBCN) thin film, can be a major solution for the ever-increasing problem of overheating electronic devices. This heat spreader can dissipate heat away from hotspots on electronic devices, unlocking additional processing power. Our method is able to effectively tune the thermal and electrical conductivity of our films by modulating the carbon content of the precursor used in a chemical vapor deposition (CVD) process. Using this method, we can generate a heat spreader that is electrically insulative, so it will not have the potential to create shorts, like graphene and metals. Additionally, we can maximize the thermal conductivity, obtaining a value of 460±149 W/m·K, which rivals or even surpasses hexagonal boron nitride (hBN). As our precursor material is 10 times cheaper than the most common hBN precursor, this is an economical alternative to hBN for heat spreader applications.

### TECHNICAL FIELD

The present technology generally relates to heat spreaders used for thermal management applications, which disperse the heat away from device hot spots by having excellent thermal conductivity. Specifically, embodiments of the present invention relate to a heat spreader composed of hexagonal boron carbon nitride with a high thermal conductivity. It additionally concerns the adjustment of the thermal and electrical conductivities of this hexagonal boron carbon nitride heat spreader through the method of the controlling the carbon content of the material, allowing optimal tuning of the heat spreader.

### BACKGROUND

With the size of electronic devices decreasing while their power increases there is an increasing amount of heat that gets trapped in these devices. Additionally localized hot spots form, limiting the overall performance of the device. This creates a desperate need for heat spreaders to dissipate heat from hot spots found on various electronic components such as IC chips and thermal interface materials to transfer heat into heat sinks. More materials with a high thermal conductivity and low electrical conductivity are needed to increase the performance of these heat spreaders.

Graphene and hexagonal boron nitride (hBN) have demonstrated high thermal conductivity and have been utilized for thermal transport applications. Thin films tend to have higher performance compared to other versions as graphene and hBN possess a higher thermal conductivity with fewer amounts of layers. These films can be used as heat spreaders to effectively disperse heat away from hot spots on electronic devices.

Graphene and other metals with high thermal conductivities have the drawback, that they are often electrically conductive. This electrical conductivity is undesirable because it adds the risk of creating electrical shorts in devices. hBN is electrically insulative so it is more suitable for these types of applications, but its thermal conductivity is far less than that of graphene. It is therefore desirable, to create a material that is electrically insulative while being able to surpass hBN thermally. Additionally, as these materials are relatively expensive, low-cost alternatives are desired.

### SUMMARY

In order to solve the problems above, the present disclosure aims to provide a heat spreader that has a maximized thermal conductivity while maintaining a low electrical conductivity. This heat spreader is composed of a hexagonal boron carbon nitride thin film which is a hybrid material between graphene and hBN. The invention is generated using chemical vapor deposition utilizing a variety of precursor chemicals to deposit a thin film on a copper substrate. Furthermore, the thermal and electrical conductivity can be adjusted by modifying the amount of carbon in the precursor. This allows the film to be able to maximize thermal conductivity while keeping the electrical conductivity sufficiently low, making it an ideal material to solve the problems listed above. The thin film can then be transferred to the desired electronic device using PMMA. (FIG. 1) Once it is placed on the device, the film will effectively dissipate heat away from any hot spots on the electronic device without creating a short on the device.

### BRIEF DESCRIPTION OF THE DRAWINGS

FIG. 1 is a perspective view of installing this invention as a heat spreader,

FIG. 2 is a diagram of the CVD setup for BCN thin films accompanied with molecular structures of the 3 precursors used, trimethylamine borane (TMAB), dimethylamine borane (DMAB) and monomethylamine borane (MMAB).

FIG. 3A is the N1s x-ray photoelectron spectroscopy (XPS) spectra for T-BCN.

FIG. 3B is the N1s XPS spectra for D-BCN.

FIG. 3C is the N1s XPS spectra for M-BCN.

FIG. 3D is the N1s XPS spectra for hBN.

FIG. 4A is the B1s XPS spectra for T-BCN.

FIG. 4B is the B1s XPS spectra for D-BCN.

FIG. 4C is the B1s XPS spectra for M-BCN.

FIG. 4D is the B1s XPS spectra for hBN.

FIG. 5A is the N1s XPS spectra for T-BCN.

FIG. 5B is the N1s XPS spectra for D-BCN.

FIG. 5C is the N1s XPS spectra for M-BCN.

FIG. 6A is an atomic force microscopy (AFM) image of the reference hBN sample.

FIG. 6B is a depth profile showing the thickness of the reference hBN sample.

FIG. 7A is an AFM image of the hBCN film grown from methylamine borane (M-BCN).

FIG. 7B is a depth profile showing the thickness of the hBCN film grown from methylamine borane (M-BCN).

FIG. 8A is an AFM image of the hBCN film grown from dimethylamine borane (D-BCN).

FIG. 8B is a depth profile showing the thickness of the hBCN film grown from dimethylamine borane (D-BCN).

FIG. 9A is an AFM image of the hBCN film grown from trimethylamine borane (T-BCN).

FIG. 9B is a depth profile showing the thickness of the hBCN film grown from trimethylamine borane (T-BCN).

FIG. 10 is a chart of the thermal conductivity data calculated from optothermal method compared with the results from data from Zhou et al. (marked *) measured few-layer hBN generated by CVD.

FIG. 11 is a chart of electrical conductivity measurements obtained by a 4-point probe.

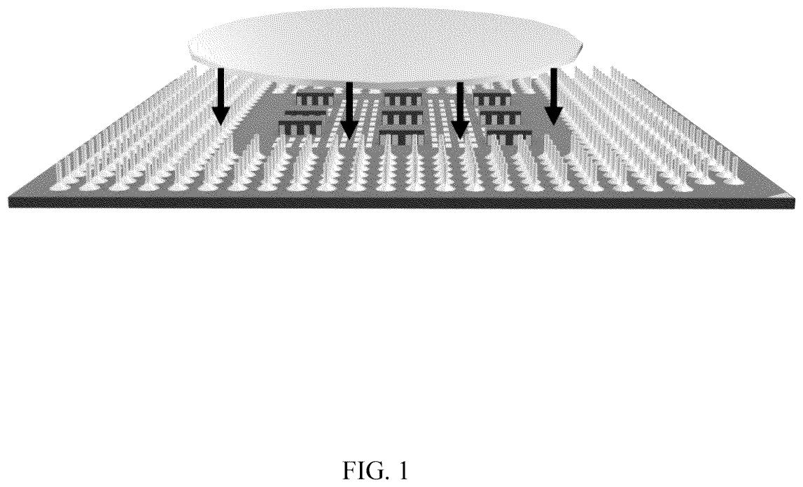

### DESCRIPTION OF EMBODIMENTS

Various embodiments are described below. It should be noted that the specific embodiments are not intended as an exhaustive description or as a limitation to the broader aspects discussed herein. One aspect described in conjunction with a particular embodiment is not necessarily limited to that embodiment and can be practiced with any other embodiment(s).

As used herein, “about” will be understood by persons of ordinary skill in the art and will vary to some extent depending upon the context in which it is used. If there are uses of the term which are not clear to persons of ordinary skill in the art, given the context in which it is used, “about” will mean up to plus or minus 10% of the particular term.

The use of the terms “a” and “an” and “the” and similar referents in the context of describing the elements (especially in the context of the following claims) are to be construed to cover both the singular and the plural, unless otherwise indicated herein or clearly contradicted by context. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the embodiments and does not pose a limitation on the scope of the claims unless otherwise stated. No language in the specification should be construed as indicating any non-claimed element as essential.

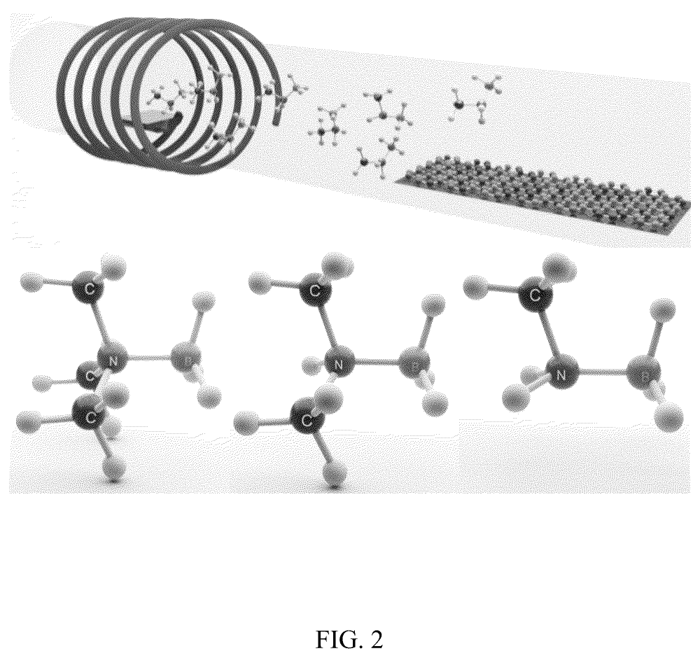

Herein we report a heat spreader composed of hexagonal boron carbon nitride with tunable thermal and electrical conductivities. The primary advantage of this invention is the ability to control the amount of carbon and its arrangement in the thin film, which allows both the thermal conductivity and the electrical conductivity to be tuned. We used a CVD process to create 3 hBCN films from 3 different precursors that differ only in the amount of carbon, (FIG. 2) methylamine borane, dimethylamine borane and trimethylamine borane. The detailed growth parameters are listed below. Our single source precursor system makes the process much simpler and faster while still giving us control over the carbon content. Our precursors also have the advantage of being much less expensive than ammonia borane, which is the primary precursor for hBN, with dimethylamine costing ten times less than ammonia borane. Additionally, by forming carbon channels within the BCN matrix our hBCN thin films can rival or even succeed the thermal conductivity of hBN thin film which we measured to be 313±86 W/m·K, while still possessing lower electrical conductivities, with many samples acting as electrical insulators. By controlling the carbon content, we are able to manipulate thermal and electrical conductivities to desirable values.

After the thin films are grown, they can be transferred using PMMA spin coating and iron chloride etching to be directly applied to the surface of the electronic device. Thin films such as our invention are optimal for heat spreader applications as they have to deal with less interfacial phonon scattering. Additionally, the alignment of carbon atoms in is more likely to occur in bottom-up processes such as our CVD based system rather than top-down processes such as doping graphene oxide. These carbon channels are crucial for providing high thermal conductivity.

### Embodiments

Embodiment 1. An hBCN thin film from dimethylamine borane. A pristine piece of copper foil is immersed in acetic acid, washed with DI water, and dried, before being placed in a tube furnace (FIG. 2). 10 mg of Dimethylamine borane is placed in a quartz boat 42 cm away from the copper foil. After the tube is sealed, the tube furnace is centered on the copper foil and heated to 1045° C. with 200 standard cubic centimeters per minute (sccm) of argon. When the furnace has reached 1045° C. the copper is annealed for 20 minutes with 10 sccm of hydrogen added. Next, the annealing continues for another 30 minutes with the H₂ flow increased to 20 sccm. An external band heater centered over the quartz boat is turned on for 2 hours at 110° C. Afterwards, the furnace and the band heater are turned off and moved from the sample to allow fast cooling.

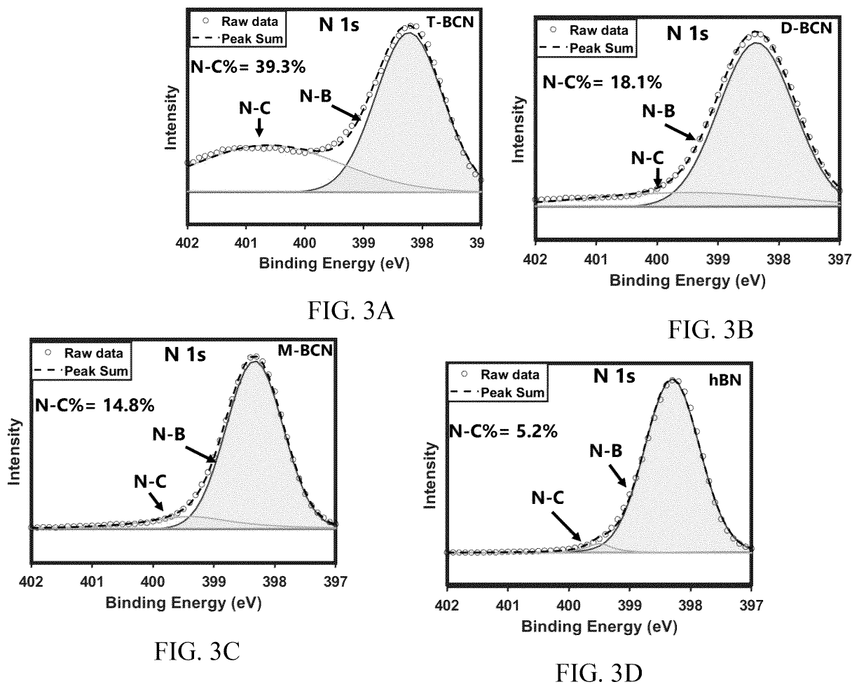

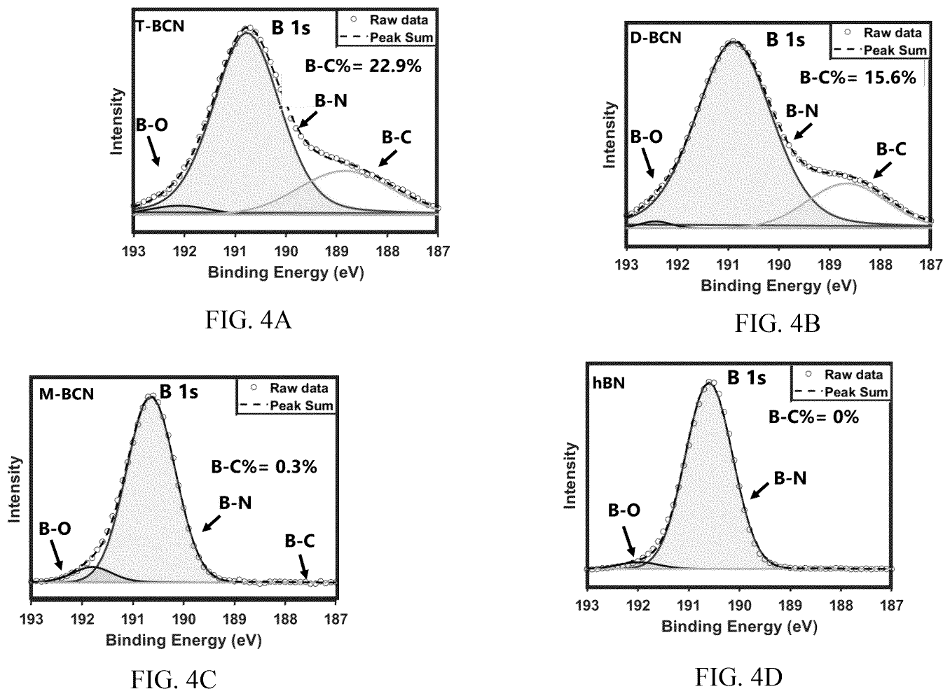

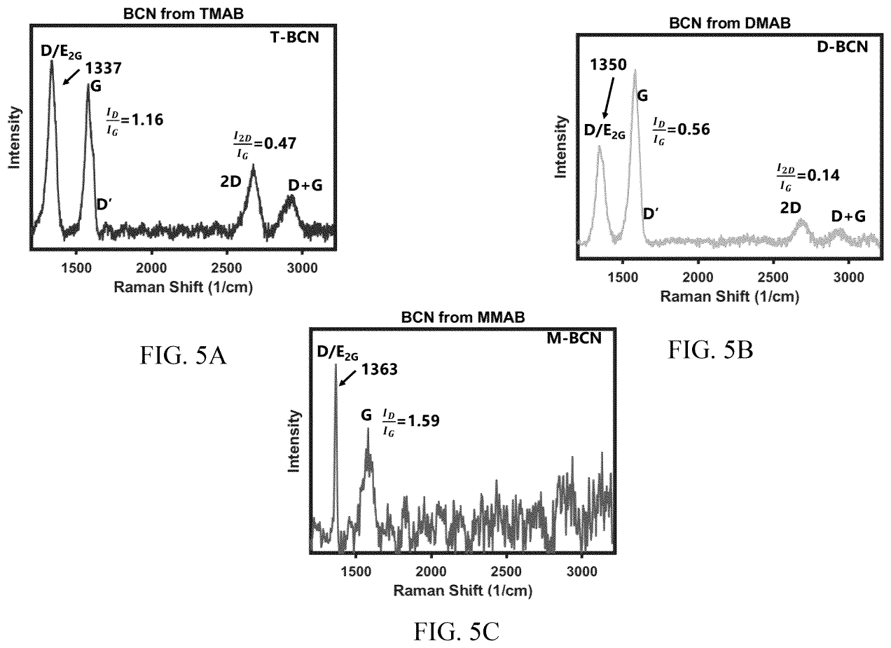

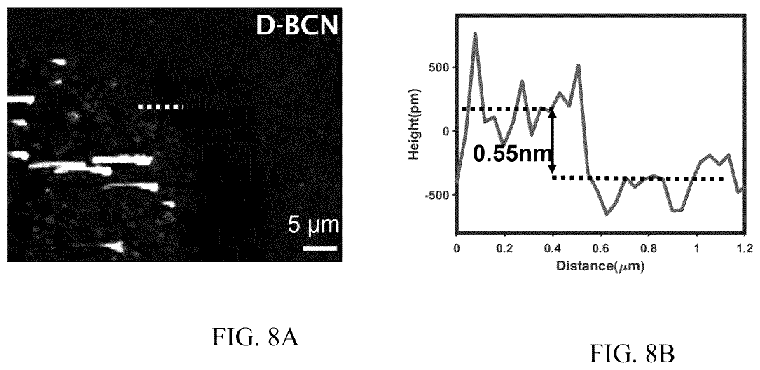

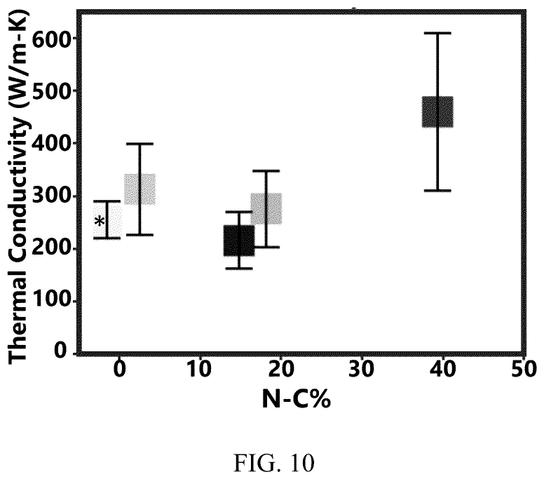

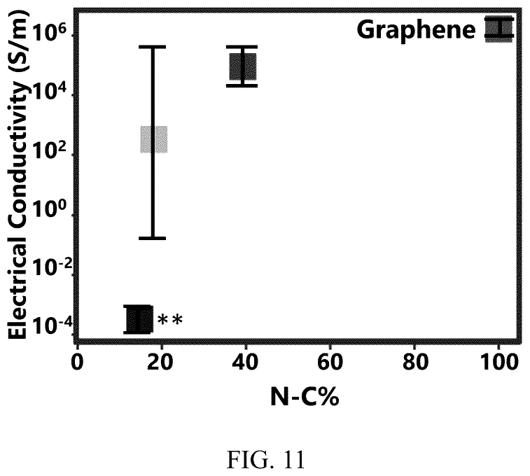

This sample labeled as D-BCN contains a moderate amount of carbon based on the N1s XPS (FIG. 3B), B1S XPS (FIG. 4B) and Raman spectroscopy (FIG. 5B) and is about 0.55 nm thick based on AFM (FIG. 8B). The thermal conductivity measured by the Raman optothermal is 275±72 W/m·K (FIG. 10). The electrical conductivity ranges from an electrical insulator to on the order of 10³ S/m (FIG. 11).

Embodiment 2. An hBCN thin film from trimethylamine borane. A pristine piece of copper foil is immersed in acetic acid, washed with DI water and dried, before being placed in a tube furnace. 10 mg of trimethylamine borane is placed in a quartz boat 56 cm away from the copper foil with a magnet on the outer edge and an ice bag placed over the top. After the tube is sealed, the tube furnace is centered on the copper foil and heated to 1045° C. with 200 sccm of argon. When the furnace has reached 1045° C. the copper is annealed for 20 minutes with 10 sccm of hydrogen added. The annealing continues for another 30 minutes with the H₂ flow increased to 20 sccm. The magnet is then used to push the quartz boat to 44 cm away from the copper. After 20 minutes, the furnace and the band heater are turned off and moved from the sample to allow fast cooling.

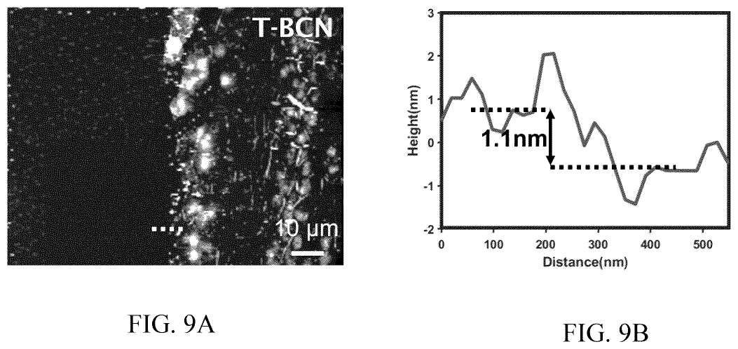

This sample labeled as T-BCN contains a large amount of carbon based on N1s XPS (FIG. 3A), B1S XPS (FIG. 4A) and Raman spectroscopy (FIG. 5A) and is about 1.1 nm thick based on AFM (FIG. 9B). The thermal conductivity measured by the Raman optothermal is 275±72 W/m·K (FIG. 10). The electrical conductivity is on the order of 10⁵ S/m, which is higher but still significantly lower than the electrical conductivity of graphene (FIG. 11).

Embodiment 3. An hBCN thin film using a combination of two precursors. A pristine piece of copper foil is immersed in acetic acid, washed with DI water and dried, before being placed in a tube furnace. 8 mg of dimethylamine borane and 2 mg of trimethylamine borane is placed in a quartz boat 42 cm away from the copper foil with an ice bag over the top. After the tube is sealed, the tube furnace is centered on the copper foil and heated to 1045° C. with 200 sccm of argon. When the furnace has reached 1045° C. the copper is annealed for 20 minutes with 10 sccm of hydrogen added. The annealing continues for another 30 minutes with the H₂ flow increased to 20 sccm. An external band heater centered over the quartz boat is turned on for 1.5 hours at 110° C. The furnace and the band heater are turned off and moved from the sample to allow fast cooling. Based off of trends in the data this sample will have a carbon level between D-BCN and T-BCN, with a corresponding intermediate thermal and electrical conductivity, with the exact value dependent on the ratio of the precursors used.

Embodiment 4. Application of hBCN as a heat spreader. 2 drops of PMMA solution are spin coated onto the sample and allowed to cure for 20 min. The copper is then etched away in a saturated solution of iron (III) chloride in a 1:1 ratio with hydrochloric acid. The sample is then transferred to 2 different DI water baths for washing. Finally, the film is transferred directly to the electronic device and allowed to dry at 80° C. for 15 min. The PMMA is subsequently removed in a bath of hot acetone.

Embodiment 5. Tuning of the thermal and electrical conductivity of hexagonal boron carbon nitride thin films based on the carbon content of the precursor. 3 different precursors, Methylamine Borane, Dimethylamine Borane and Trimethyl Amine borane, labeled as M-BCN, D-BCN and T-BCN, respectively have been examined. The N1s XPS (FIGS. 3A-3D), B1S XPS (FIGS. 4A-4D) and Raman spectroscopy (FIGS. 5A-5C) both demonstrate a clear increase in the caron content of the film as carbon is added going from M-BCN to D-BCN to T-BCN. The N1s and B1s XPS spectra both increase the percentage of nitrogen or boron bonded to carbon as the carbon content of the precursor increases. For Raman spectra there are several trends that can also indicate the amount of carbon in hBCN. As the carbon content increased, the D peak red shifts as it moves from the E_{2G} peak position of ˜1370 1/cm to the D peak position around ˜1345 1/cm. Additionally, it has been observed that the D/G ratio and 2D/G ratio increase with carbon content, until the D/G ratio peaks at a 90% carbon content and then decreases to the point where the D peak is not noticeable for pristine graphene as the lattice becomes more ordered. Similarly, the D′ peak at ˜1620 1/cm is more prominent between carbon contents of 75 to 95%. All of our samples agree with the red shift trend as we shift from 1363 to 1337 with increasing carbon content. We also see the D/G and 2D/G peak trends with D-BCN and T-BCN and TBCN possessing a D′ peak making it look like 75% carbon spectra. The M-BCN is the exception as it appears to just be hBN lightly doped with carbon, with a prominent E_{2G} peak and a small G peak.

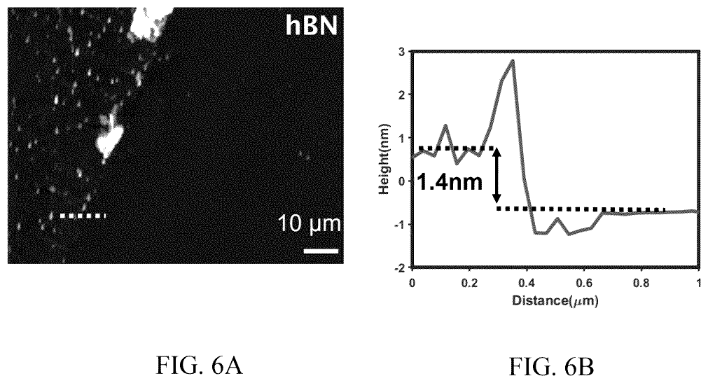

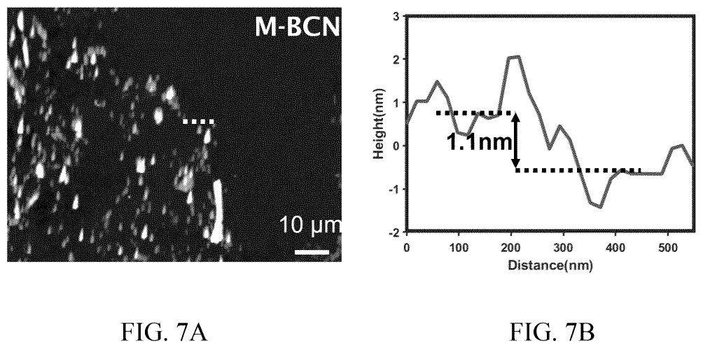

By varying the carbon content, we are able to successfully tune the thermal and electrical conductivity in thin films that range from 0.55 to 1.4 nm (FIGS. 6A-9B). We measure the thermal conductivity utilizing the optothermal method, which uses the Raman shift at various temperatures and the Raman shift with varying laser power to relate the laser power with the resulting temperature change which allows us to calculate the thermal conductivity. Using this technique, we calculated the thermal conductivities to be 313±86 216±53, 275±72 and 460±149 W/m·K for hBN, M-BCN, D-BCN and T-BCN and compared it to a previously measure value of hBN grown by CVD (FIG. 10). We notice that there is an initial decrease in thermal conductivity when carbon is added to hBN due to excess phonon scattering at the new BN/Carbon interfaces. But as we add more carbon it begins to form conductive channels that allow its thermal conductivity to surpass even hBN.

Similarly, we measured the electrical conductivity using a 4-point probe and also notice a trend where the electrical conductivity is increasing with carbon content, although our highest carbon content sample still has less electrical conductivity than graphene (FIG. 11). Our low carbon sample, M-BCN is too insulative to be correctly measured, but the value can be calculated using the IV curves. We also notice that our middle sample D-BCN has wide error bars due to some samples also being insulative. This indicates that when properly tuning the parameters D-BCN can rival hBN's insulative properties while matching and possibly even eventually surpassing its thermally conductive properties.

While certain embodiments have been illustrated and described, it should be understood that changes and modifications can be made therein in accordance with ordinary skill in the art without departing from the technology in its broader aspects as defined in the following claims.

The embodiments, illustratively described herein may suitably be practiced in the absence of any element or elements, limitation or limitations, not specifically disclosed herein. Thus, for example, the terms “comprising,” “including,” “containing,” etc. shall be read expansively and without limitation. Additionally, the terms and expressions employed herein have been used as terms of description and not of limitation, and there is no intention in the use of such terms and expressions of excluding any equivalents of the features shown and described or portions thereof, but it is recognized that various modifications are possible within the scope of the claimed technology.

The present disclosure is not to be limited in terms of the particular embodiments described in this application. Many modifications and variations can be made without departing from its spirit and scope, as will be apparent to those skilled in the art. Functionally equivalent methods and compositions within the scope of the disclosure, in addition to those enumerated herein, will be apparent to those skilled in the art from the foregoing descriptions. Such modifications and variations are intended to fall within the scope of the appended claims. The present disclosure is to be limited only by the terms of the appended claims, along with the full scope of equivalents to which such claims are entitled. It is to be understood that this disclosure is not limited to particular methods, reagents, compounds, compositions, or biological systems, which can of course vary. It is also to be understood that the terminology used herein is for the purpose of describing particular embodiments only, and is not intended to be limiting.

All publications, patent applications, issued patents, and other documents referred to in this specification are herein incorporated by reference as if each individual publication, patent application, issued patent, or other document was specifically and individually indicated to be incorporated by reference in its entirety. Definitions that are contained in text incorporated by reference are excluded to the extent that they contradict definitions in this disclosure.

What is claimed is:

1. A heat spreader, comprising:
a hexagonal boron caron nitride thin film;
wherein the thin film is applied to the surface of an electronic device.

2. The heat spreader according to claim 1, wherein the heat spreader contains boron carbon and nitrogen.

3. The heat spreader according to claim 1, wherein the heat spreader is between 0.3 and 10 nm thick.

4. The heat spreader according to claim 1, wherein the heat spread was produced using chemical vapor deposition.

5. The heat spreader according to claim 1, wherein the precursor is composed of methylamine borane, dimethylamine borane, trimethyl amine borane or tri methyl borazine.

6. The heat spreader according to claim 1, wherein the precursor is composed of any combination of methylamine borane, dimethylamine borane, trimethyl amine borane or tri methyl borazine.

7. A method of adjusting the thermal and electrical conductivity of hexagonal boron carbon nitride thin films, comprising;
modifying the carbon content of the chemical precursor used in a chemical vapor deposition process used to make hexagonal boron carbon nitride.

8. The method according to claim 7, wherein the modification of the carbon content of the precursor is used to adjust the thermal conductivity.

9. The method according to claim 7, wherein the modification of the carbon content of the precursor is used to adjust the electrical conductivity.
